(19) United States
(12) Patent Application Publication
(10) Pub. No.: US 2012/0153350 A1
(43) Pub. Date: Jun. 21, 2012

(54) SEMICONDUCTOR DEVICES AND METHODS FOR FABRICATING THE SAME

(75) Inventors: Stephan KRONHOLZ, Dresden (DE); Gunda BEERNINK, Dresden (DE); Ina OSTERMAY, Coswig (DE)

(73) Assignee: GLOBALFOUNDRIES Inc., Grand Cayman (KY)

(21) Appl. No.: 12/971,691

(22) Filed: Dec. 17, 2010

(51) Int. Cl. H01L 29/165; H01L 21/335

(52) U.S. Cl. 257/190; 438/191; 257/E29.085; 257/E21.403

(57) ABSTRACT

Embodiments of semiconductor devices and methods for fabricating the semiconductor devices are provided. The method includes forming a cavity in a semiconductor region laterally adjacent to a gate electrode structure of a transistor. The gate electrode structure is disposed on a channel region of a first silicon-germanium alloy. A strain-inducing silicon-germanium alloy is formed in the cavity and in contact with the first silicon-germanium alloy. The strain-inducing silicon-germanium alloy includes carbon and has a composition different from the first silicon-germanium alloy.

### FIELD OF THE INVENTION

The present invention relates generally to semiconductor devices and methods for fabricating semiconductor devices, and more particularly relates to semiconductor devices with transistors having enhanced performance by using a strain-inducing silicon-germanium alloy in the drain and source regions to enhance charge carrier mobility in the channel region of the transistor, and methods for fabricating such semiconductor devices.

### BACKGROUND OF THE INVENTION

The majority of present day integrated circuits (ICs) are implemented by using a plurality of interconnected field effect transistors (FETs), also called metal oxide semiconductor field effect transistors (MOSFETs), or simply MOS transistors. A FET includes a gate electrode structure as a control electrode and spaced apart source and drain electrodes between which a current can flow. A control voltage applied to the gate electrode structure controls the flow of current through a channel region between the source and drain electrodes.

The gain of an FET, usually defined by the transconductance (gₘ), is proportional to the mobility of the majority carrier in the transistor channel region. The current carrying capability of an MOS transistor is proportional to the transconductance times the width of the channel region divided by the length of the channel (gₘ W/l). FETs are usually fabricated on silicon substrates with a (100) crystallographic surface orientation, which is conventional for silicon technology. For this and many other orientations, the mobility of holes, the majority carrier in a P-channel FET (PFET), can be increased by applying a compressive longitudinal stress to the channel region. A compressive longitudinal stress can be applied to the channel region of a FET by embedding an expanding material such as pseudomorphic silicon germanium formed by a selective epitaxial growth process in the silicon substrate at the ends of the transistor channel region (epitaxial silicon germanium at the ends of the transistor channel also referred to herein as “eSiGe”). A silicon germanium crystal has a greater lattice constant than the lattice constant of a silicon crystal, and consequently the presence of embedded silicon germanium causes a deformation of the silicon matrix that, in turn, compresses the material in the channel region.

The material used to form the transistor channel region also affects the charge carrier mobility of the channel region. Various alloys of silicon germanium have also been found to be suitable materials for forming transistor channels region (channel silicon germanium also referred to herein as “cSiGe”), and particularly for forming channel regions of PFET devices. However, the two different silicon germanium layers, i.e., eSiGe and cSiGe, will typically have different compositions with different corresponding lattice structures and lattice constants. Where these two layers interface, laterally below the gate electrode structure, dislocations or lattice disconnects can occur as a result of the different lattice structures and constants. These dislocations result in current leakage. Moreover, these dislocations can be further exaggerated during heat treating and annealing processes typically used during the latter steps of fabricating the semiconductor devices.

Accordingly, it is desirable to provide semiconductor devices and methods for fabricating semiconductor devices where the field effect transistor has enhanced charge carrier channel mobility with reduced current leakage. Furthermore, other desirable features and characteristics of the present invention will become apparent from the subsequent detailed description and the appended claims, taken in conjunction with the accompanying drawings and the foregoing technical field and background.

### SUMMARY OF THE INVENTION

Semiconductor devices and methods for fabricating semiconductor devices are provided herein. In accordance with an exemplary embodiment, a method for fabricating a semiconductor device is provided. The method includes forming a cavity in a semiconductor region laterally adjacent to a gate electrode structure of a transistor. The gate electrode structure is disposed on a channel region of a first silicon-germanium alloy. A strain-inducing silicon-germanium alloy is formed in the cavity and is in contact with the first silicon-germanium alloy. The strain-inducing silicon-germanium alloy includes carbon and has a composition different from the first silicon-germanium alloy.

In accordance with another exemplary embodiment, a method for fabricating a semiconductor device is provided. The method includes forming a strain-inducing silicon-germanium alloy in a cavity formed in an active region of a P-type transistor such that the strain-inducing silicon-germanium alloy is in contact with a first silicon-germanium alloy that forms a channel region of the P-type transistor. The first silicon-germanium alloy has a composition different from the strain-inducing silicon-germanium alloy which includes carbon. Drain and source regions are formed at least partially in the strain-inducing silicon-germanium alloy.

In accordance with another exemplary embodiment, a semiconductor device is provided. The semiconductor device includes a silicon-containing semiconductor region. A channel region is formed of a first silicon-germanium alloy that is formed in the silicon-containing semiconductor region. A gate electrode structure is formed above the channel region. Drain and source regions are formed in the silicon-containing semiconductor region adjacent to the channel region. A strain-inducing silicon-germanium alloy includes carbon and is formed at least partially in the drain and source regions. The strain-inducing silicon-germanium alloy is in contact with the first silicon-germanium alloy and has a composition different from the first silicon-germanium alloy. A metal silicide is formed in the strain-inducing silicon-germanium alloy and at least partially in the drain and source regions.

### BRIEF DESCRIPTION OF THE DRAWINGS

Embodiments of the present invention will hereinafter be described in conjunction with the following drawing figures, wherein like numerals denote like elements, and wherein:

FIGS. 1-6 schematically illustrate, in cross-sectional views, a semiconductor device during stages of its fabrication in accordance with exemplary embodiments.

### DETAILED DESCRIPTION

The following Detailed Description is merely exemplary in nature and is not intended to limit the invention or the application and uses of the invention. Furthermore, there is no intention to be bound by any theory presented in the preceding Background of the Invention or the following Detailed Description.

Various embodiments contemplated herein relate to semiconductor devices and methods for fabricating semiconductor devices. During intermediate stages of the fabrication of a semiconductor device, a cavity is formed in a semiconductor region laterally adjacent to a gate electrode structure of a transistor. The gate electrode structure is disposed on a channel region that is formed from a channel silicon-germanium alloy layer (cSiGe). A strain-inducing silicon-germanium alloy layer (eSiGe) is then formed in the cavity and is in contact with the cSiGe layer. The eSiGe layer contains a relatively low amount of carbon and has a composition different from the cSiGe layer, and accordingly, the eSiGe and cSiGe layers likely have different corresponding lattice structures and lattice constants. In an exemplary embodiment, the carbon content of the eSiGe layer is of from about 0.05 to about 0.2 atomic percent, and more preferably is about 0.1 atomic percent. The inventors have found that by having a relatively low amount of carbon in the eSiGe layer, dislocations between the eSiGe and cSiGe layers are reduced or minimized, and more preferably, are eliminated, with little to no effect on the compressive strain applied to the channel by the eSiGe layer. Without being limited by theory, it is believed that some of the carbon present in the eSiGe layer is arranged substitutionally on the lattice side of the silicon-germanium crystalline structure, replacing some of the silicon and locally relaxing the strain enough at the interface between the two layers to reduce dislocations. The other major portion of the carbon is believed to be arranged on the interfacial side of the silicon-germanium crystalline structure to capture or block dislocations. Thus, the transistor preferably has enhanced charge carrier channel mobility because of the compressive strain that the eSiGe layer produces in the channel, and further, the transistor preferably has reduced current leakage due to the reduction or elimination of dislocations between the eSiGe and cSiGe layers.

Referring to FIG. 1, a schematic depiction of a cross-sectional view of a semiconductor device 10 in an intermediate fabrication stage in accordance with an exemplary embodiment is provided. The semiconductor device 10 includes a substrate 12. Above the substrate 12 is a semiconductor layer 14, which may represent a silicon-containing semiconductor material that includes a high fraction of silicon in a crystalline state. As shown, a buried insulating layer 16 is positioned between the substrate 12 and the semiconductor layer 14, and the combination of layers 12, 14 and 16 represents a silicon-on-insulator (SOI). In other cases, the semiconductor layer 14 may be formed on a crystalline semiconductor material of the substrate 12, thereby providing a “bulk” configuration. It should be appreciated that an SOI configuration and a bulk configuration may be used concurrently in the device 10 in different device areas if considered advantageous.

In an exemplary embodiment, an isolation structure 18 is provided in the semiconductor layer 14. The isolation structure 18 defines corresponding active regions 20 and 22, which are to be understood as semiconductor regions having formed therein and or receiving an appropriate dopant profile as required for forming transistor elements. In one example, the active regions 20 and 22 correspond to the active region of a transistor 24 and a transistor 26, which represent an N-channel transistor and a P-channel transistor, respectively.

As shown, the transistors 24 and 26 include corresponding gate electrode structures 28 and 30. The gate electrode structures 28 and 30 may include the same or different electrode material or materials 32, such as silicon, silicon-germanium, metal-containing materials and the like, followed by a oxide layer 33 and a cap layer 34. The oxide layer 33 may be silicon dioxide and the alike, and the cap layer may be silicon nitride and the like. The gate electrode structures 28 and 30 also include a gate insulation layer 36 that separates the electrode material 32 from the channel regions 38 and 40 of the transistors 24 and 26. Further, the gate electrode structure 28 of the transistor 24 is encapsulated by a spacer layer 42, which also covers the active region 20. On the other hand, the electrode material 32 of the gate electrode structure 30 of the transistor 26 is encapsulated by the cap layer 34 and a sidewall spacer 44, which may be silicon nitride and the like. The width 46 of the spacer 44 substantially defines a lateral offset of the cavity to be formed in the active region 22. In an exemplary embodiment, the channel region 40 of the transistor 26 is formed of cSiGe that has electronic characteristics of which may be enhanced, at least locally, on the basis of a strain inducing mechanism. As illustrated, the channel region 40 is part of a silicon-germanium layer 48 that spans a substantial upper surface portion of the active region 22. Preferably, the cSiGe layer of the channel region 40 has a germanium concentration of from about 20 to about 40 atomic percent, and more preferably of from about 28 to about 32 atomic percent.

The semiconductor device 10 as shown in FIG. 1 may be formed on the basis of the following processes. After forming the isolation structure 18, involving lithography, etch, deposition, planarization techniques and the like, the basic doping of the active regions 20 and 22 may be established, for instance, by ion implantation. Next, the silicon-germanium layer 48 is formed, involving lithography techniques, etch, selective epitaxial growth, planarization techniques and the alike. Thereafter, the gate electrode structures 28 and 30 including the oxide layer 33 and the cap layer 34 may be formed by forming an appropriate layer stack and patterning the same on the basis of lithography and etch techniques. Next, the spacer layer 42 may be deposited, and an etch mask 50, such as a resist mask, may be formed so as to cover the spacer layer 42 about the transistor 24 while exposing the layer 42 about the transistor 26. Thereafter, an anisotropic etch process may be performed so as to etch the exposed portion of the spacer layer 42, thereby forming the sidewall spacer 44 and exposing the cap layer 34.

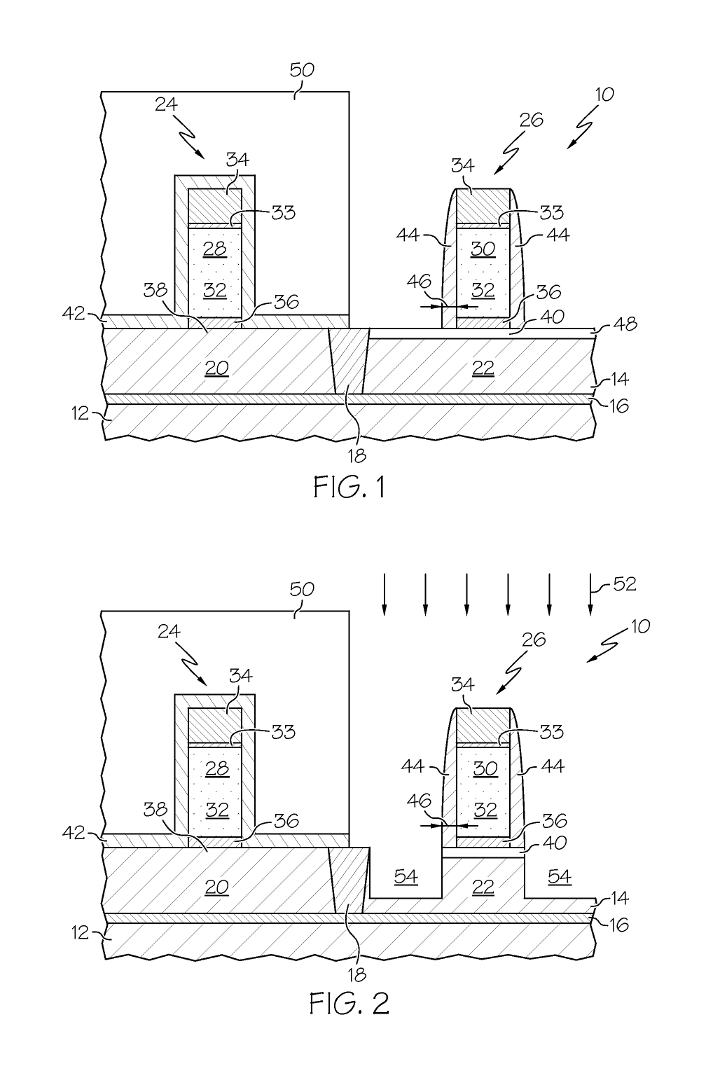

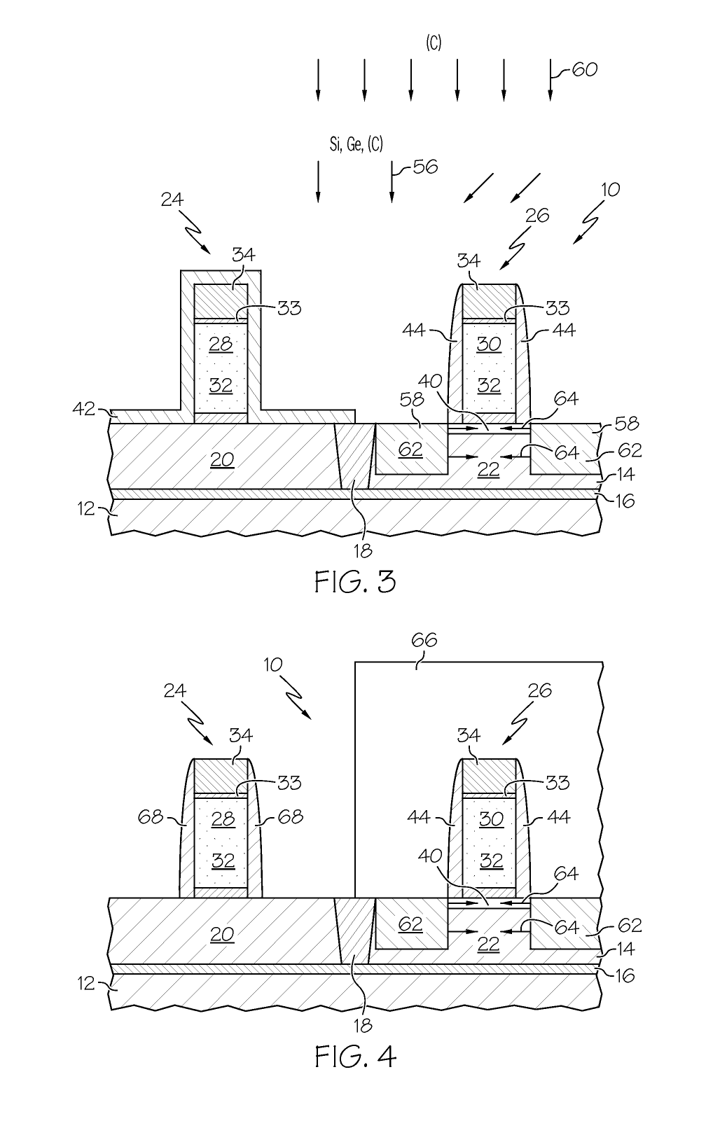

Referring to FIG. 2, a schematic depiction of the semiconductor device 10 in a further advanced fabrication stage in accordance with an exemplary embodiment is provided. An etch process 52 is performed to form the cavity 54. In one example, the etch mask 50 covers the transistor 24 and surrounding area while leaving the transistor 26 and surrounding silicon-germanium layer 48 exposed. The etch process 52 may represent an etch sequence for forming the sides spacers 44 and the cap layer 34, and subsequently etching through the exposed portion of the silicon-germanium layer 48, and further, into the active region 22 to form the cavity 54. It should be appreciated that the cavity 54 may be formed on both sides of the gate electrode structure 30, while, in other cases, one of these sides may be masked if an asymmetric transistor configuration with respect to the eSiGe layer (shown in FIG. 3) is to be provided. It should further be appreciated that the cavity 54 may be formed on the basis of a substantially anisotropic etch behavior accomplished on the basis of a plasma assisted etch, while, in other cases, the cavity 54 may be formed by wet chemical etch chemistries, which may have a crystallographic anisotropic etch behavior, or on the basis of a combination of plasma assisted and wet chemical etch chemistries. In an exemplary embodiment, the portion of the silicon-germanium layer 48, which is protected by the sidewall spacers 44 and the gate electrode structure 30 including the cap layer 34, remaining after the etch process 52 defines the channel region 40.

Referring to FIG. 3, a schematic depiction of the semiconductor device 10 in a further advanced fabrication stage in accordance with an exemplary embodiment is provided. As shown, the device 10 is exposed to a selective epitaxial growth process 56 to form a silicon-germanium layer 58 within the cavity 54. In one example, the selective epitaxial growth process 56 may be established on the basis of a silicon and germanium-containing precursor gas and appropriate process parameters in order to obtain a selective deposition of a silicon-germanium alloy within the cavity 54 while substantially avoiding a material deposition on the dielectric surfaces, such as the isolation structure 18, the cap layer 34, the spacer layer 42 and the sidewall spacer 44. In this example, carbon is introduced into the silicon-germanium layer 58 by ion implantation 60 in a subsequent process, and thereby, forming the eSiGe layer 62 that contains carbon. In an alternative example, the selective epitaxial growth process 56 includes a suitable precursor gas and appropriate process parameters to obtain a selective deposition of a silicon-germanium alloy with carbon to form the eSiGe layer 62 that contains carbon. In another exemplary embodiment, the carbon content of the eSiGe layer 62 is preferably of from about 0.05 to about 0.2 atomic percent, and more preferably of about 0.1 atomic percent.

As a consequence, after the deposition of the eSiGe layer 62, which effectively acts as a strain-inducing silicon-germanium layer, a compressive strain component 64 in the channel region 40 and the underlying active region 22 may be substantially determined by the germanium content of the eSiGe layer 62 and the lateral offset from the channel region 40. In an exemplary embodiment, the eSiGe layer 62 has a germanium concentration that is less than a germanium concentration of the cSiGe alloy of the channel region 40. Preferably, the germanium concentration of the eSiGe layer 62 is of from about 19 to about 26 atomic percent, and more preferably of from about 22 to about 24 atomic percent. In at least one embodiment, the compressive strain component 64 is increased and more fully realized from subsequent annealing and heat treating processes of which there may be several during later fabrication stages that may be conducted for various purposes including activating the atomic germanium species in the eSiGe layer 62 to position the germanium into lattice sites in the silicon-germanium alloy.

As discussed above, because the eSiGe layer 62 has a composition different from the cSiGe layer of the channel region 40, the eSiGe and cSiGe layers 62 and 40 likely have different corresponding lattice structures and lattice constants. The inventors have found that by having a relatively low amount of carbon in the eSiGe layer 62, dislocations between the eSiGe and cSiGe layers 62 and 40 are reduced and/or minimized, and more preferably, are eliminated, with little to no effect on the compressive strain component 64 applied to the channel region 40 by the strain-inducing eSiGe layer 62.

Referring to FIG. 4, a schematic depiction of the semiconductor device 10 in a further advanced fabrication stage in accordance with an exemplary embodiment is provided. As shown, an etch mask 66, such as a resist mask, may be formed so as to cover the transistor 26 and the upper surface of the eSiGe layer 62, while exposing the spacer layer 42 above the transistor 24. Thereafter, an anisotropic etch process may be performed so as to etch the exposed portion of the spacer layer 42, thereby forming the sidewall spacer 68 and exposing the cap layer 34 of the transistor 24.

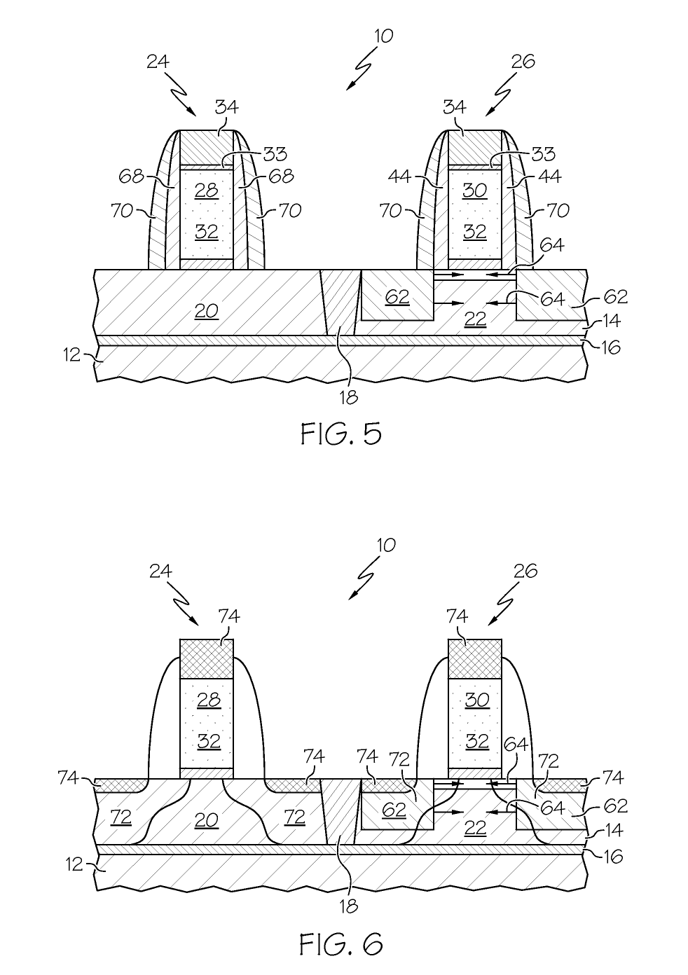

Referring to FIG. 5, a schematic depiction of the semiconductor device 10 in yet further advanced fabrication stage in accordance with exemplary embodiment is provided. As illustrated, sacrificial oxide spacers 70 may be formed over the sidewall spacers 68 and 44 of the transistors 24 and 26. The sacrificial oxide spacers 70 are formed by depositing an oxide layer, such as, for example, silicon dioxide over the sidewall spacers 68 and 44 and then anisotropically etching the oxide layer. The sacrificial oxide spacers 70 can function as an etch mask for removing the cap layer 34 during a subsequent fabrication stage.

Referring to FIG. 6, the semiconductor device 10 in accordance with one or more exemplary embodiments is formed on the basis of the following processes. After forming the eSiGe layer 62 and the sacrificial oxide spacers 70 as previously described, the sacrificial oxide spacers 70, the cap layers 34 and the oxide layers 33 may be removed and further processing may be continued by appropriate implantation processes on the basis of well-established techniques. Moreover, the sidewall spacers 44 and 68 may be further defined in accordance with process and device requirements so as to act as an implantation mask, at least at various fabrication stages of the implantation sequences, in order to establish the desired vertical and lateral dopant profiles for the drain and source regions 72. Thereafter, one or more annealing processes may be performed to activate the dopants. Next, the device 10 may be prepared for depositing a refractory metal, such as, for example, cobalt, nickel, titanium, tantalum, platinum, palladium, rhodium, and mixtures thereof, which may be accomplished on the basis of well-established cleaning recipes. Thereafter, the layer of the refractory metal may be deposited and subsequently one or more heat treatments may be performed to initiate a chemical reaction to form metal silicide 74. It should be appreciated that the carbon content contained in the eSiGe layer 62 will function to reduce or eliminate dislocations between the eSiGe and the cSiGe layers 62 and 40 during these latter fabrication stages including during the annealing and heat treating processes.

Accordingly, semiconductor devices and methods for fabricating semiconductor devices have been described. The various embodiments include during intermediate stages of the fabrication of the semiconductor device, forming a cavity in a semiconductor region laterally adjacent to a gate electrode structure of a transistor. The gate electrode structure is disposed on a channel region that is formed from a channel silicon-germanium alloy layer, i.e., cSiGe. A strain-inducing silicon germanium alloy layer, i.e., eSiGe, is then formed in the cavity and is in contact with the channel region. The eSiGe layer contains a relatively low amount of carbon and has a composition different from the cSiGe layer, and accordingly, the eSiGe and the cSiGe layers likely have different corresponding lattice structures and lattice constants. The relatively low amount of carbon in the eSiGe layer has been found to reduce or eliminate dislocations between the two silicon-germanium layers that would otherwise occur because of the differences in their lattice structures and lattice constants. Moreover, the relatively low amount of carbon in the eSiGe layer has been found to have little or no effect on the compressive strain applied to the channel region. Thus, the transistor preferably has enhanced charge carrier channel mobility because of the compressive strain that the eSiGe layer produces in the channel, and further, the transistor preferably has reduced current leakage due to the reduction or elimination of dislocations between the eSiGe and cSiGe layers.

While at least one exemplary embodiment has been presented in the foregoing Detailed Description, it should be appreciated that a vast number of variations exist. It should also be appreciated that the exemplary embodiments are only examples, and are not intended to limit the scope, applicability, or configuration of the invention in any way. Rather, the foregoing Detailed Description will provide those skilled in the art with a convenient road map for implementing an exemplary embodiment of the invention, it being understood that various changes may be made in the function and arrangement of elements described in an exemplary embodiment without departing from the scope of the invention as set forth in the appended Claims and their legal equivalents.

What is claimed is:

1. A method for fabricating a semiconductor device, the method comprising:
forming a cavity in a semiconductor region laterally adjacent to a gate electrode structure of a transistor, wherein the gate electrode structure is disposed on a channel region of a first silicon-germanium alloy; and
forming a strain-inducing silicon-germanium alloy in the cavity and in contact with the first silicon-germanium alloy, the strain-inducing silicon-germanium alloy comprises carbon and has a composition different from the first silicon-germanium alloy.

2. The method according to claim 1, wherein forming the strain-inducing silicon-germanium alloy comprises forming the strain-inducing silicon-germanium alloy having a carbon content of from about 0.05 to about 0.2 atomic percent.

3. The method according to claim 2, wherein forming the strain-inducing silicon-germanium alloy comprises forming the strain-inducing silicon-germanium alloy having the carbon content of about 0.1 atomic percent.

4. The method according to claim 1, wherein forming the strain-inducing silicon-germanium alloy comprises performing a selective epitaxial growth process to grow a silicon-germanium layer in the cavity.

5. The method according to claim 4, wherein forming the strain-inducing silicon-germanium alloy comprises in situ doping the silicon-germanium layer with carbon during the epitaxial growth process to define the strain-inducing silicon-germanium alloy.

6. The method according to claim 4, wherein forming the strain-inducing silicon-germanium alloy further comprises introducing the carbon into the silicon-germanium layer by performing an ion implantation process.

7. The method according to claim 1, wherein the first silicon-germanium alloy has a first germanium concentration, and the strain-inducing silicon-germanium alloy has a second germanium concentration that is less than the first germanium concentration.

8. The method according to claim 7, wherein the first germanium concentration is of from about 28 to about 32 atomic percent.

9. The method according to claim 7, wherein the second germanium concentration is of from about 19 to about 26 atomic percent.

10. The method according to claim 1, further comprising forming drain and source regions at least partially in the strain-inducing silicon-germanium alloy.

11. The method according to claim 10, further comprising forming a metal silicide in the strain-inducing silicon-germanium alloy and at least partially in the drain and source regions.

12. The method according to claim 11, wherein forming a metal silicide comprises depositing metal on an upper surface of the strain-inducing silicon-germanium alloy and performing a heat treatment to initiate a chemical reaction of the metal and silicon that is contained in the strain-inducing silicon-germanium alloy, the metal is selected from the group consisting of cobalt, nickel, titanium, tantalum, platinum, palladium, rhodium, and mixtures thereof.

13. A method for fabricating a semiconductor device, the method comprising:
forming a strain-inducing silicon-germanium alloy in a cavity formed in an active region of a P-type transistor such that the strain-inducing silicon-germanium alloy is in contact with a first silicon-germanium alloy that defines a channel region of the P-type transistor, the first silicon-germanium alloy having a composition different from the strain-inducing silicon-germanium alloy which comprises carbon; and
forming drain and source regions at least partially in the strain-inducing silicon-germanium alloy.

14. The method according to claim 13, wherein the strain-inducing silicon-germanium alloy has a carbon content of from about 0.05 to about 0.2 atomic percent.

15. The method according to claim 13, further comprising forming a metal silicide in the strain-inducing silicon-germanium alloy and at least partially in the drain and source regions, the metal silicide formed from metal selected from the group consisting of cobalt, nickel, titanium, tantalum, platinum, palladium, rhodium, and mixtures thereof.

16. The method according to claim 13, wherein forming the strain-inducing silicon-germanium alloy comprises performing a selective epitaxial growth process to grow a silicon-germanium layer in the cavity.

17. The method according to claim 16, wherein the silicon-germanium layer is doped with the carbon as formed from the epitaxial growth process to define the strain-inducing silicon-germanium alloy.

18. The method according to claim 16, wherein forming the strain-inducing silicon-germanium alloy further comprises introducing the carbon into the silicon-germanium layer by performing an ion implantation process.

19. A semiconductor device comprising:
a silicon-containing semiconductor region;
a channel region formed of a first silicon-germanium alloy formed in the silicon-containing semiconductor region;
a gate electrode structure formed above the channel region; drain and source regions formed in the silicon-containing semiconductor region adjacent to the channel region;
a strain-inducing silicon-germanium alloy comprising carbon formed at least partially in the drain and source regions, the strain-inducing silicon-germanium alloy contacting the first silicon-germanium alloy and having a composition different from the first silicon-germanium alloy; and
a metal silicide formed in the strain-inducing silicon-germanium alloy and at least partially in the drain and source regions.

20. The semiconductor device according to claim 19, wherein the strain-inducing silicon-germanium alloy has a carbon content of from about 0.05 to about 0.2 atomic percent.
